(19) United States
(12) Patent Application Publication
(10) Pub. No.: US 2012/0292761 A1
(43) Pub. Date: Nov. 22, 2012

(54) BONDING PAD STRUCTURE AND INTEGRATED CIRCUIT COMPRISING A PLURALITY OF BONDING PAD STRUCTURES

(76) Inventors: Yu-Ju Yang, Hsin-Chu City (TW); Chih-Hung Lu, Hsinchu City (TW)

(21) Appl. No.: 13/565,759

(22) Filed: Aug. 2, 2012

Related U.S. Application Data
(62) Division of application No. 12/983,895, filed on Jan. 4, 2011.

(30) Foreign Application Priority Data
Dec. 13, 2010 (TW) 099143454

(51) Int. Cl. H01L 23/498

(52) U.S. Cl. 257/737; 257/E23.068

(57) ABSTRACT

A bonding pad structure positioned on an integrated circuit includes a connecting pad, an insulation layer and a gold bump. The connecting pad is formed on the integrated circuit. The insulation layer is formed on the connecting pad, where the insulation layer has only one opening and a shape of the opening includes at least a bend. The gold bump is formed on the insulation layer, where the gold bump is electrically connected to the connecting pad through the opening of the insulation layer.

### CROSS REFERENCE TO RELATED APPLICATIONS

This divisional application claims the benefit of co-pending U.S. patent application Ser. No. 12/983,895, filed on Jan. 4, 2011, and incorporated herein by reference.

### BACKGROUND OF THE INVENTION

1. Field of the Invention

The present invention relates to a bonding pad structure, and more particularly, to a bonding pad structure which is disposed on an integrated circuit and is applied to chip on glass (COG) and chip on film (COF) packages.

2. Description of the Prior Art

Please refer to FIG. 1. FIG. 1 is a diagram illustrating a COG structure 100. As shown in FIG. 1, the COG structure 100 includes a driver integrate circuit (IC) 110, an anisotropic conductive film (ACF) 120 and a glass substrate 130, where the driver IC 110 includes a plurality of bonding pad structures 112, the ACF 120 is composed of adhesive 122 and conductive particles 124, and a plurality of electrodes 132 which correspond to the bonding pad structures 112 are formed on the glass substrate 130.

During the COG bonding procedure, first, the ACF 120 is disposed on the glass substrate 130. Then, the bonding pad structures 112 of the driver IC 110 are aligned with the electrodes 132 of the glass substrate 130, and the driver IC 110 and the glass substrate 130 are pressed together under a specific temperature, speed and pressure to make the bonding pad structures 112 of the driver IC 110 electrically connect to the electrodes 132 of the glass substrate 130 via the conductive particles 124 of the ACF 120 and to make the driver IC 110 adhere to the glass substrate 130 via the adhesive 122. FIG. 2 shows the pressed COG structure. As a person skilled in this art should understand details of the COG bonding procedure, further descriptions are omitted here for brevity.

In addition, because of the higher resolution of the liquid crystal display (LCD), a quantity of the pins of the driver IC 110 (i.e., a quantity of the bonding pad structures 112) is increased and a pitch of two bonding pad structures becomes smaller. Considering the smaller pitch of the bonding pad structures 112, the ACF 120 having smaller conductive particles (about 3-4 um) is used to prevent shorting between two bonding pad structures 112.

Please refer to FIG. 3. FIG. 3 is a cross-section view of the bonding pad structure 112 shown in FIG. 1 and FIG. 2. As shown in FIG. 3, the bonding pad structure 112 includes a connecting pad 302, an insulation layer 304 formed on the connecting pad 302, and a gold bump 306 formed on the connecting pad 302 and the insulation layer 304. The formation of the gold bump 306 on the connecting pad 302 and the insulation layer 304 leads to the surface of the gold bump 306 being dented. Therefore, if the size of the conductive particles is too small, the conductivity between the bonding pad structures 112 of the driver IC 110 and the electrodes 132 of the glass substrate 130 will be influenced because not enough conductive particles are broken while the COG package is formed.

### SUMMARY OF THE INVENTION

It is therefore an objective of the present invention to provide a bonding pad structure whose gold bump has a flat surface to have a better conductivity with an electrode disposed on the glass substrate after pressing together with the glass substrate.

According to one embodiment of the present invention, a bonding pad structure positioned on an integrated circuit includes a connecting pad, an insulation layer and a gold bump. The connecting pad is formed on the integrated circuit. The insulation layer is formed on the connecting pad, where the insulation layer has only one opening and a shape of the opening includes at least a bend. The gold bump is formed on the insulation layer, where the gold bump is electrically connected to the connecting pad through the opening of the insulation layer.

According to another embodiment of the present invention, an integrated circuit includes a plurality of bonding pad structures, where each of the bonding pad structures includes a connecting pad, an insulation layer and a gold bump. The connecting pad is formed on the integrated circuit. The insulation layer is formed on the connecting pad, where the insulation layer has only one opening and a shape of the opening includes at least a bend. The gold bump is formed on the insulation layer, where the gold bump is electrically connected to the connecting pad through the opening of the insulation layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a COG structure.

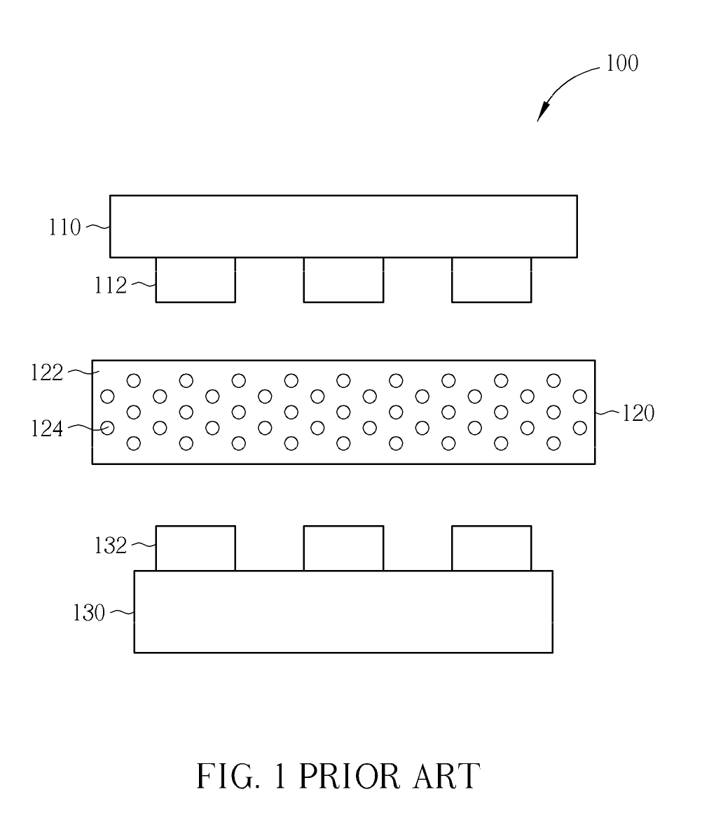

FIG. 2 shows the pressed COG structure.

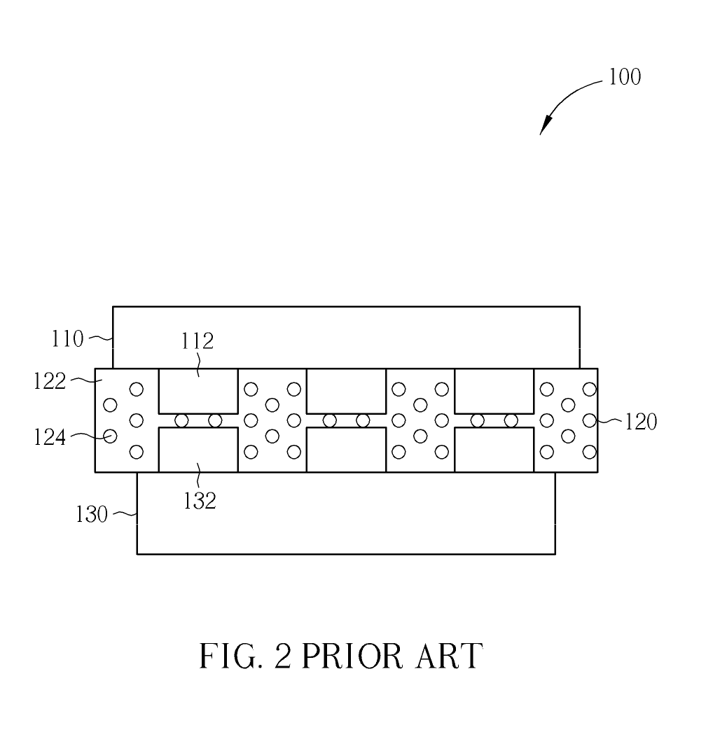

FIG. 3 is a cross-section view of the bonding pad structure shown in FIG. 1 and FIG. 2.

FIG. 4 is a diagram illustrating a COG structure according to one embodiment of the present invention.

FIG. 5 is a diagram illustrating a bonding pad structure according to one embodiment of the present invention.

FIG. 6 shows an opening of an insulation layer shown in FIG. 4 having an “O” shape.

FIG. 7 shows the opening of the insulation layer shown in FIG. 4 having an “S” shape.

FIG. 8 shows the opening of the insulation layer shown in FIG. 4 having a “fish-bone” shape.

### DETAILED DESCRIPTION

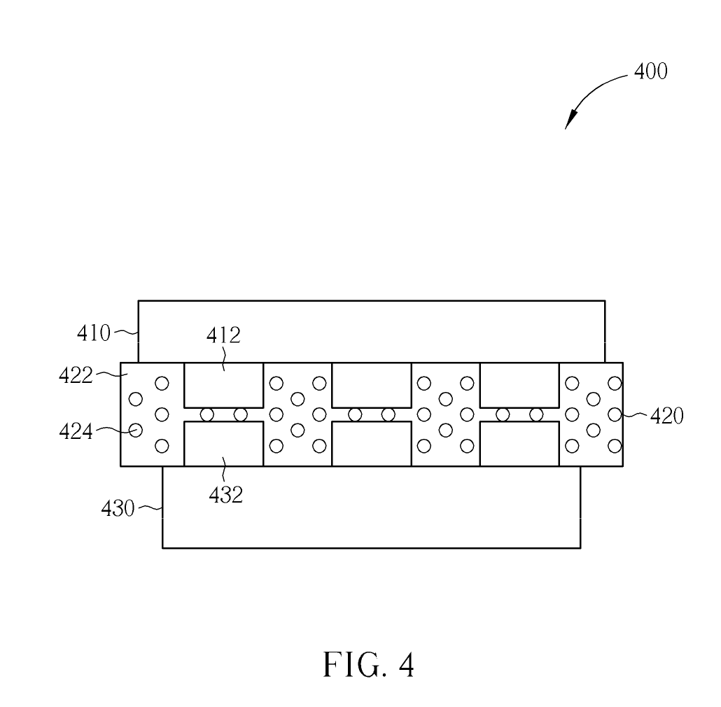

Please refer to FIG. 4. FIG. 4 is a diagram illustrating a COG structure 400 according to one embodiment of the present invention. Referring to FIG. 4, the COG structure 400 includes a driver IC 410, an ACF 420 and a glass substrate 430, where the driver IC 410 includes a plurality of bonding pad structures 412, the ACF 420 is composed of adhesive 422 and conductive particles 424, and a plurality of electrodes 432 which correspond to the bonding pad structures 412 are disposed on the glass substrate 430. The bonding pad structures 412 of the driver IC 410 can be electrically connected to the electrodes 432 of the glass substrate 430 via the conductive particles 424 of the ACF 420, and the driver IC 410 is adhered to the glass substrate 430 by the adhesive 422.

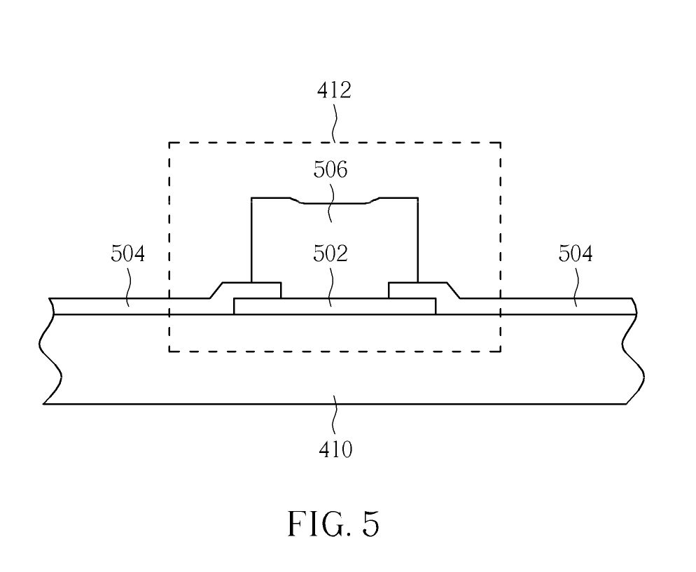

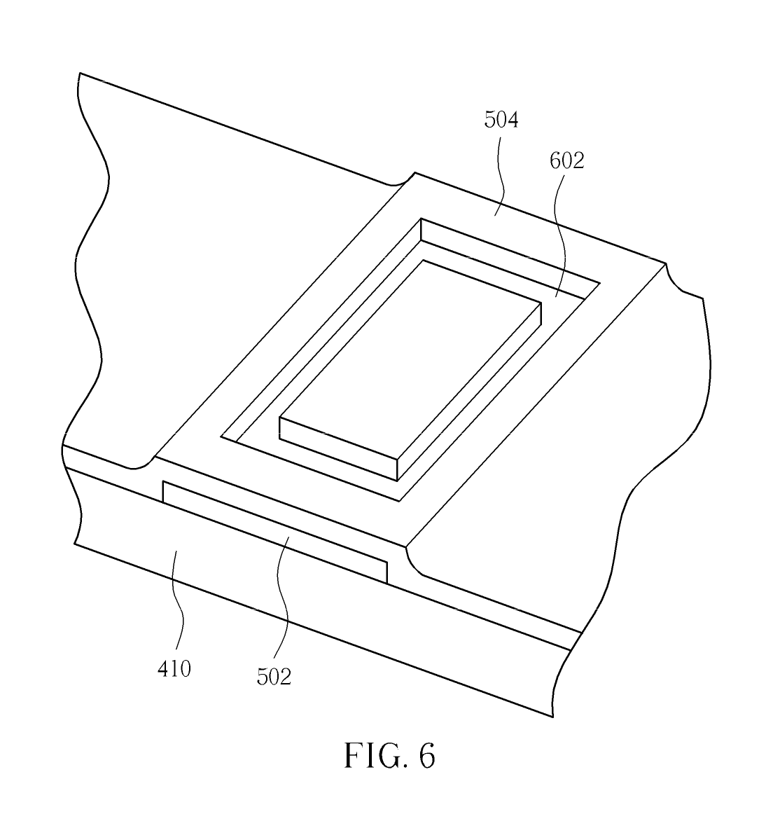

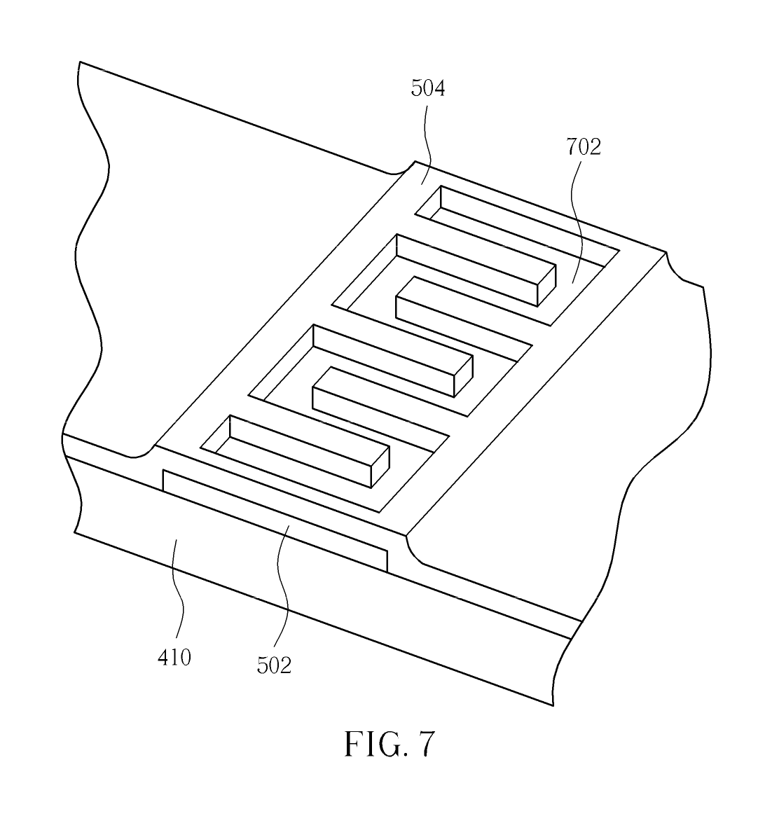

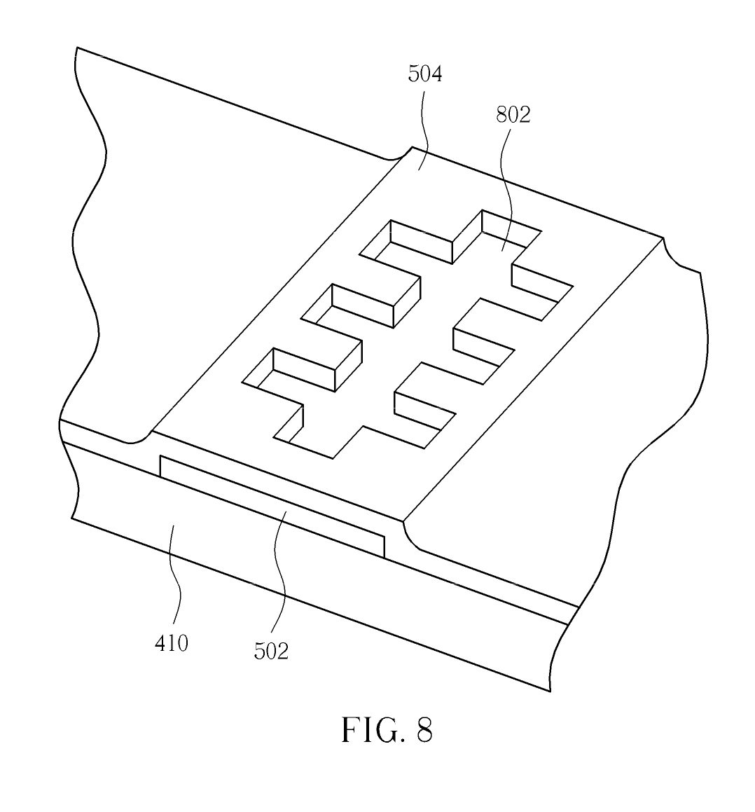

Please refer to FIG. 5. FIG. 5 is a diagram illustrating a bonding pad structure 412 according to one embodiment of the present invention. As shown in FIG. 5, the bonding pad structure 412 includes a connecting pad 502, an insulation layer 504 formed on the connecting pad 502, and a gold bump 506 formed on the connecting pad 502 and the insulation layer 504, where the insulation layer 504 has only one opening, and the opening includes at least a bend. For example, please refer to FIGS. 6, 7 and 8, which respectively show the openings 602, 702, 802 of the insulation layer 504 can be an “O” shape, an “S” shape and a “fish-bone” shape, and the gold bump 506 is directly formed on the insulation layer 504 and the openings 602, 702, 802 to make the gold bump 506 electrically connect to the connecting pad 502 through the openings 602, 702, 802.

In addition, although FIGS. 6-8 show the “O” shape, the “S” shape and the “fish-bone” shape, these embodiments are not meant to be limitations of the present invention. In other embodiments of the present invention, the opening of the insulation layer 504 can be any combination of the “O” shape, the “S” shape and the “fish-bone” shape (e.g., the opening includes both “O” and “fish-bone” shapes) or their simple modifications (e.g., “U” shape or inverse “S” shape). In other words, as long as the opening has at least a bend, these alternative designs should fall within the scope of the present invention. In addition, the “bend” here does not need to be a right-angle bending as shown in FIGS. 6-8; “bend” can also encompass a non-right angle bending or curve bending.

In addition, the material of the gold bump 506 can be copper, nickel, gold or any combination thereof, or Sn—Pb alloy, and is formed on the insulation layer by electroplating.

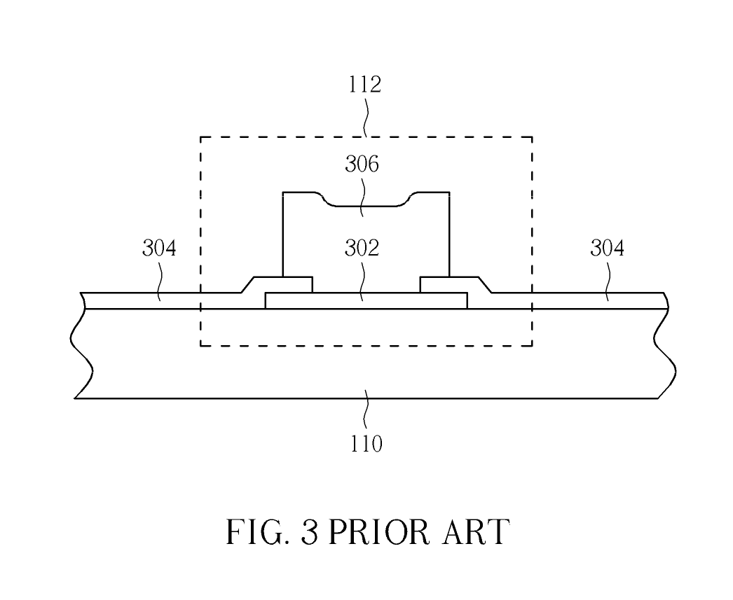

Because the opening of the insulation layer 504 has at least a bend such as the openings shown in FIGS. 6-8, the drop height of the gold bump 506 is greatly decreased. Taking the gold bumps having the same surface area as an example, if the drop height of the gold bump of the conventional bonding pad structure shown in FIG. 3 is turn, the drop height of the gold bump of the bonding pad structure of the present invention is less than 1 um. Therefore, the surface of the gold bump is flatter, and a sufficient number of conductive particles 424 are broken when the driver IC 410 and the glass substrate 430 are pressed together, resulting in improved conductivity between the bonding pad structures 412 and the electrodes 432.

Because the drop height of the gold bump of the bonding pad structure 412 is very small, the ACF 420 can adopt smaller conductive particles 424 without losing conductivity. Therefore, the pitch of the bonding pad structure 412 can be further decreased to increase the density of the gold bump on the driver IC 410.

In addition, the above-mentioned disclosure takes COG package as an example; however, the driver IC 410 of the present invention can also be applied to a COF package. That is, the glass substrate 430 shown in FIG. 4 can be replaced by a film having a plurality of electrodes, and the driver IC 410 and the film are pressed together by ACF or eutectic bonding. In addition, the driver IC 410 of the present invention can also be applied to a flexible printed circuit board (FPC) and a rigid printed circuit board, that is, the glass substrate 430 shown in FIG. 4 can be replaced by a flexible printed circuit board (FPC) or a rigid printed circuit board having a plurality of electrodes, and the driver IC 410 and the FPC/rigid printed circuit board are pressed together by ACF or eutectic bonding.

Briefly summarized, the insulation layer of the bonding pad structure has only one opening, and the opening includes at least a bend. Therefore, the surface of the gold bump is flatter, and the conductivity between the bonding pad structures and the electrodes is better.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A bonding pad structure, positioned on an integrated circuit, comprising:
a connecting pad, formed on the integrated circuit;
an insulation layer, formed on the connecting pad, wherein the insulation layer has only one opening and a shape of the opening includes at least a bend; and
a gold bump, formed on the insulation layer, wherein the gold bump is electrically connected to the connecting pad through the opening of the insulation layer;
wherein the opening comprises an “O” shaped opening area.

2. An integrated circuit comprising a plurality of bonding pad structures, wherein each of the bonding pad structures comprises:
a connecting pad, formed on the integrated circuit;
an insulation layer, formed on the connecting pad, wherein the insulation layer has only one opening and a shape of the opening includes at least a bend; and
a gold bump, formed on the insulation layer, wherein the gold bump is electrically connected to the connecting pad through the opening of the insulation layer;
wherein the opening comprises an “O” shaped opening area.
